(19) United States
(12) Patent Application Publication
(10) Pub. No.: US 2003/0141887 A1
(43) Pub. Date: Jul. 31, 2003

(54) Integrated circuit testing device with improved reliability

(76) Inventor: Stephane Briere, Bourguebus (FR)

Correspondence Address: PHILIPS ELECTRONICS NORTH AMERICAN CORP, 580 WHITE PLAINS RD, TARRYTOWN, NY, 10591, US

(21) Appl. No.: 10/257,298

(22) PCT Filed: Mar. 12, 2002
(86) PCT No.: PCT/IB02/00752

(30) Foreign Application Priority Data
Mar. 13, 2001 (FR) 0103415

(51) Int. Cl. G01R 31/26

(52) U.S. Cl. 324/765

(57) ABSTRACT

The invention relates to an integrated circuit testing device. It comprises:

means (3) for generating and applying, at the input of an integrated circuit under test (1) and at the input of a reference integrated circuit (2), input signals and

means (4) for comparing, in real time, output signals delivered at the output of the integrated circuit under test (1) and at the output of the reference integrated circuit (2), in response to the input signals, in order to determine whether the integrated circuit under test is in order or is faulty.

The integrated circuits (1 and 2) are mounted in parallel and receive simultaneously the input signals simulating the input signals that the integrated circuits would receive in the functional situation

This testing device is used, in particular, to test integrated circuits for decoding digital television signals.

The present invention relates to an integrated circuit testing device. This device is more specifically, yet not exclusively, suited for integrated circuits intended for the processing of large volumes of data, such as decoder circuits for digital signals encoded in accordance with MPEG type standards.

The present invention also relates to a method of testing integrated circuits.

It is desired that the integrated circuits that are put onto the market have as few faults as possible. Conventional testing devices generate input stimuli and apply these to the various input pins of the integrated circuit under test, the output signals that appear on the output pins of the integrated circuit are collected and compared with predictive output signals and, according to the results of the comparison, the integrated circuit is considered to be either in order or defective.

Integrated circuits are becoming more and more complex, they have increasingly large numbers of input and output pins and they are becoming faster and faster.

With such testing devices, the integrated circuits cannot be fully checked. It is only possible to find out their structural faults. Functional faults may go unnoticed. They are only discovered when the integrated circuits are operational in their application, that is to say after they have been delivered to the customer. Such faults can be very damaging to the reputation of the integrated circuit manufacturer, and thus also in economic terms, since a manufacturer of faulty circuits risks losing customers.

It would require an enormous storage space to make the test more comprehensive and thus more reliable.

American patent U.S. Pat. No. 6,055,661 describes a testing device using a reference integrated circuit that is of the same type as that to be tested and has been considered to be in order.

This reference integrated circuit is mounted in an executive circuit that is intended to execute an executive program. The latter generates input signals to be applied to the reference integrated circuit. The reference integrated circuit delivers output signals that are collected and stored. The input signals are also applied to the integrated circuit under test, but with a delay. The integrated circuit under test delivers output signals that are collected and stored. A comparison is then carried out between the output signals delivered by the reference integrated circuit and those delivered by the integrated circuit under test, taking into account the delay introduced. Using the result of the comparison, it can be determined whether the integrated circuit under test is in order or faulty.

It is not necessary to generate input stimuli and store these in the memory, since the input signals are generated by the executive circuit. The executive circuit provides additional flexibility concerning the input signals to be applied to the integrated circuit under test.

But this device nevertheless requires a lot of memory space to store the output signals appearing at the output of the reference integrated circuit and, at the same time, at the output of the integrated circuit under test before they are compared. Moreover, the introduction of the delay greatly complicates the operation of the testing device. In fact, the output signals have to be perfectly synchronized at the time of their comparison. The testing time increases because in practice the reference integrated circuit is tested before the integrated circuit under test.

The present invention is an integrated circuit testing device with improved reliability that does not have the memory capacity and synchronization problems mentioned above.

To this end the testing device in accordance with the invention comprises:

input means for generating input signals and applying these input signals to the input of an integrated circuit under test and to the input of a reference integrated circuit that is considered to be in order, and

comparison means for comparing in real time output signals delivered at the output of the integrated circuit under test and at the output of the reference integrated circuit in response to the input signals, in order to determine, dependent upon the result of the comparison, whether the integrated circuit under test is in order or faulty. The integrated circuits are mounted in parallel and receive the input signals simultaneously, with these input signals simulating the signals that the integrated circuits would receive in a functional operational situation.

The input means can comprise a central processing unit intended to generate the input signals and to cooperate with an interface module, connected on the one hand to the input of the integrated circuit under test and on the other to the input of the reference integrated circuit. The interface module duplicates the input signals that are generated by the central unit and intended for the integrated circuits.

The testing device comprises connection means intended to receive the integrated circuit under test, with the interface module being capable of powering down the connection means when an integrated circuit under test is being installed, in order to avoid short-circuits and electrical conflicts between various interfaces.

The interface module can also provide an exchange of data between the central processing unit and the integrated circuits.

The interface module can generate clock signals to be sent to the integrated circuits and the comparison means in order to guarantee correct synchronization when the tests are being carried out.

The input means can comprise a data memory that cooperates with the central processing unit, these data forming the basis of the input signals.

The input means can also comprise a program memory that cooperates with the central processing unit. This memory will then be used to store the system program that will control in particular the operation of the central processing unit.

The central processing unit can be connected to an interface intended to communicate, via a microcomputer, with a user who can thus follow the execution of the test, and generate statistical data, such as testing efficiency or also a breakdown into types of faults detected.

In a production environment, the central processing unit can be connected to a robot for management of the integrated circuits under test.

The comparison means can comprise at least one exclusive OR port.

The testing device can comprise an electrical supply provided with a section intended to deliver an adjustable voltage for feeding the integrated circuit under test and possibly the reference integrated circuit.

Such a testing device can form part of a tester.

The present invention also relates to an integrated circuit testing method that comprises the following steps:

generation of input signals to be applied simultaneously to the input of an integrated circuit under test and to the input of a reference integrated circuit considered to be in order, said input signals simulating the input signals that the integrated circuit under test and the reference integrated circuit would receive in a functional situation;

comparison, in real time, of output signals appearing, in response to input signals, at the output of the integrated circuit under test and at the output of the reference integrated circuit;

determination, dependent upon the result of the comparison, whether the integrated circuit under test is in order or faulty.

Other characteristics and advantages of the invention will become apparent from the following description, illustrated by the attached diagrams.

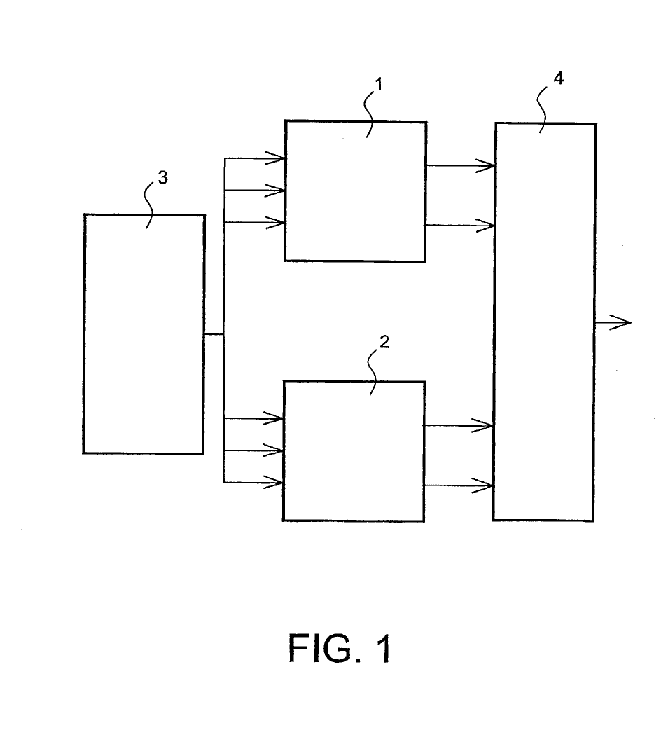

FIG. 1 is a schematic representation of a testing device in accordance with the invention.

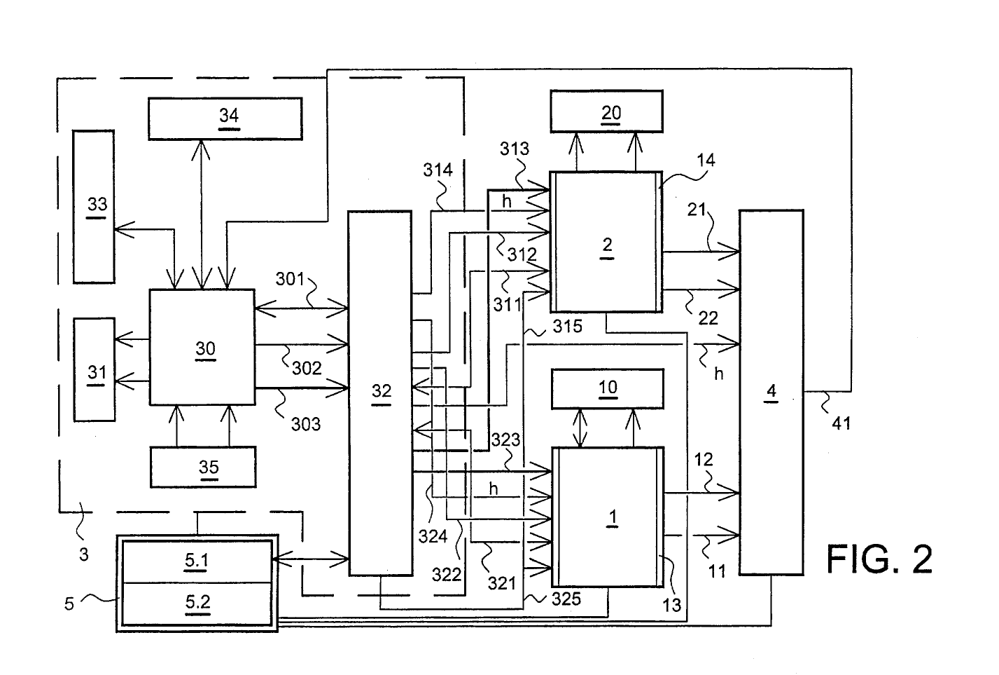

FIG. 2 is a diagram illustrating a testing device in accordance with the invention that is more specifically suited for testing digital television signal decoding integrated circuits.

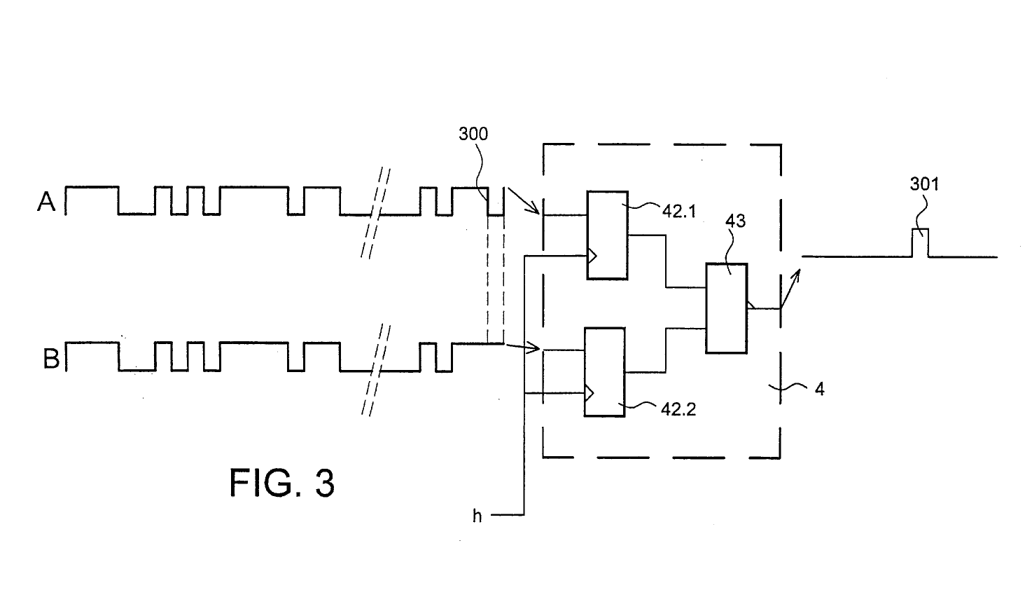

FIG. 3 illustrates the functioning of the comparison means of a testing device in accordance with the invention.

Reference is made to FIG. 1 that shows a block diagram of an integrated circuit testing device in accordance with the invention.

The testing device is intended for testing an integrated circuit 1. The integrated circuit under test 1 will be tested at the same time as a reference integrated circuit 2 that is considered to be in order and that is of the same type as the circuit under test 1. This reference integrated circuit 2 will already have been successfully tested. The two integrated circuits 1, 2 are mounted in parallel between the input means 3 intended to generate input signals and apply these input signals to them and comparison means 4 intended to compare output signals appearing at the output of the integrated circuits, in response to the input signals, in real time, as soon as they appear.

The input means 3 deliver their input signals to the two integrated circuits 1, 2 while the comparison means 4 receive the output signals delivered at the output of the integrated circuits 1, 2 in response to the input signals received.

The result of the test depends on the result of the comparison. If the output signals of the integrated circuit under test 1 are identical to those of the reference integrated circuit 2, the integrated circuit under test 1 is considered to be in order. Otherwise, the circuit under test 1 is considered to be faulty and is rejected.

In accordance with a characteristic of the invention, the input signals applied to the two integrated circuits 1, 2 are identical to the input signals that they would receive under operating conditions The integrated circuits 1, 2 are no longer subject to input stimuli that do not allow a reliable test to be carried out. Unlike the prior art, he testing device in accordance with the invention checks the true functioning of the integrated circuit under test rather than its response to artificially defined stimuli.

The two integrated circuits 1, 2 are supplied simultaneously with the input signals and the output signals are collected and routed, in real time, directly to the comparison means 4. It is no longer necessary to have memories for storing the output signals before they are compared.

The input means 3 and the output signal comparison means 4 can be included in a tester. The latter will simulate operationing conditions of the integrated circuits.

A more detailed description will now be given of an example of a testing device in accordance with the invention that is more particularly suited for testing integrated circuits intended to decode digital television signals. Reference is made to FIG. 2.

The input means 3 comprise a central processing unit 30 that generates the input signals to be applied to the integrated circuit under test 1 and to the reference integrated circuit 2. These input signals can be data or addresses intended to control the functioning of the integrated circuits, or also compressed audio and video digital data, which input signals are of the same type as the input signals that the integrated circuits receive when they decode digital television images.

The central processing unit 30 is connected to at least one data memory 31, for example of the FLASH type. It contains data allowing the central processing unit 30 to generate the input signals to be applied to the integrated circuits 1, 2. These data take up much less memory space than would have been occupied by the input signals themselves.

The central processing unit 30 is connected to at least one program memory 35, for example a read-only memory. It contains the control programs for the central processing unit 30 to carry out the test.

The central processing unit 30 is also connected to an interface module 32 that forms an interface between the central processing unit 30 and the two integrated circuits 1, 2. Between the central processing unit 30 and the interface module 32, the data are transmitted via a bus referenced 301, the addresses are transmitted via a bus referenced 302 and the audio and video data are transmitted via a bus referenced 303.

The central processing unit 30 can be connected to an interface 33 to communicate with a user via a microcomputer (not shown). The user will thus be able to follow the execution of the test and, if necessary, intervene.

In a production environment, the central processing unit 30 can be connected to an interface 34 intended to communicate with a robot for management of the integrated circuits under test 1 (not shown). This robot manages the flow of circuits to be tested and, dependent upon the test result, an integrated circuit is directed towards the batch of usable circuits or towards the batch of rejected circuits.

The interface module 32 is connected to the input of each of the integrated circuits 1, 2. Between the interface module 32 and the integrated circuit 1 under test, there is a bus referenced 311 for the data, a bus referenced 312 for the addresses and a bus referenced 313 for the audio and video data.

In the same way, between the interface module 32 and the reference integrated circuit 2, there is a bus referenced 321 for the data, a bus referenced 322 for the addresses and a bus referenced 323 for the audio and video data.

The integrated circuits 1,2, when they are in position, have their pins (not shown) connected to connection means referenced 13 for the integrated circuit under test 1 and 14 for the reference integrated circuit 2. These connection means 13, 14 form part of the testing device and receive the integrated circuits.

The buses 311, 312, 313, 321, 322, 323 lead from the side of the integrated circuits to these connection means 13, 14.

The interface module duplicates the input signals that it received from the central processing unit 30 in order to deliver these to the two integrated circuits 1, 2.

But it can also have other functions, in particular an address decoding function. The test starts with a communication step between the central processing unit 30 and the integrated circuits 1, 2 prior to the transmission of the signals simulating those that the integrated circuits 1, 2 would receive in a functional situation. It therefore allows the central processing unit 30 to exchange data with the integrated circuits in this phase.

The interface module 32 generates clock signals towards the integrated circuit under test 1 and the reference integrated circuit 2 via the buses 314, 324, respectively. The two integrated circuits 1, 2 are synchronous.

The interface module 32 also generates synchronization signals to synchronize the decoding and the output data. These signals pass through a bus referenced 315 to the integrated circuit under test 1 and via a bus referenced 325 to the reference integrated circuit 2.

The testing device comprises a power supply 5. Preferably this power supply comprises a part 5.1 that delivers a set voltage and a programmable part 5.2 delivering an adjustable voltage. The first part 5.1 delivers the set voltage in particular to the input means 3, to the reference integrated circuit 2 and to the comparison means 4. The programmable part 5.2 delivers the adjustable voltage to the integrated circuit under test 1 in order to test it at various voltages. In this way it is possible to detect faulty integrated circuits in which the fault would not have been noticed if the test had been carried out at a single supply voltage. An increase of the number of integrated circuits considered as faulty during the test, causes the number of integrated circuits rejected during operation to be reduced. The rate of coverage of the test and its reliability are increased.

In this digital integrated circuit testing application it is not necessary to perform the test by supplying power to the reference integrated circuit at different voltages.

But this possibility is conceivable in analogue applications.

The interface module 32 is also capable of powering down the connection means 13 when an integrated circuit under test is being installed. In this way any risk of short-circuits and/or electrical conflict are avoided at the time the connection is established.

In the diagram of FIG. 2, each of the integrated circuits 1, 2 is associated with a memory 10, 20, respectively. This may be a synchronous dynamic random access memory SDRAM. This memory is necessary in this application in order to enable the integrated circuits to operate. In other applications it can be dispensed with.

The signals appearing at the output of the integrated circuits 1, 2 are then compared, as soon as they appear, in real time, in the comparison means 4. In this application, use is made of a bit-by-bit comparator comprising at least one exclusive OR port.

These comparison means 4 are connected to the output of the integrated circuit under test 1 and to the output of the reference integrated circuit 2 by at least one bus. In FIG. 2, one bus for the video signals and one bus for the audio signals have been provided. These are referenced 11, 12, respectively, at the output of the integrated circuit under test 1 and 21, 22, respectively at the output of the reference integrated circuit 2. These buses 11, 12, 21, 22 are connected, on the side of the integrated circuits, to the connection means 13, 14.

The comparison means 4 deliver a signal that translates the result of the test, said signal being routed to the central processing unit via a bus referenced 41.

FIG. 3 shows the functioning of the comparison means 4 for the video signals. A chronological representation is shown of the video signals appearing at the output of the integrated circuits. The chronogram referenced A corresponds to the output signal collected at the output of the integrated circuit under test 1. The chronogram referenced B corresponds to the output signal collected at the output of the reference integrated circuit 2. These signals appear as a succession of bits. These signals are delivered, as soon as they appear, to the comparison means 4. These comparison means 4 comprise two D flip-flops, one of which, referenced 42.1, receives at its input the signals A coming from the integrated circuit under test 1, and the other, referenced 42.2, receives at its input the signals B coming from the reference integrated circuit 2. These D flip-flops 42.1, 42.2 also receive the clock signal h coming from the interface module 32. The output of the flip-flops is connected to the input of an exclusive OR port 43 that delivers a signal translating the result of the test. The D flip-flops serve to enable a bit-by-bit comparison of signals that may be slightly out of phase with each other, by performing a transient storage operation that is not contrary to the principle of real time comparison.

In this example, the bit referenced 300 of signal A corresponds to a fault, it is not found in signal B.

An exclusive OR port delivers bits with a logic value of “zero” when the bits that it receives are identical. As soon as it receives two bits with different values at its two inputs it delivers a bit with a logic value of “one”.

The signal appearing at the output of the exclusive OR port 43 has a bit 301 with a logic value of “one”, which indicates that the integrated circuit under test 1 is faulty.

In the testing device in accordance with the invention, it is no longer necessary to have memory space to store the output signals of the integrated circuits. The input signals can be applied for a sufficiently long time to the circuits to obtain a very reliable test result. If it had been desired to test an integrated circuit of this type with a testing device of the prior state of the art, the test could only have centered on a few video images and this would not have been enough to ensure that the integrated circuit did not have a fault. By way of example, a video image of 720 pixels by 520 pixels requires approximately 900 kb of memory.

Such a testing device, capable of testing in-situ integrated circuits intended to generate much output data, is particularly simple to use and low in cost. As the test is performed by comparison in real time of the output signals of the integrated circuits, storage of the output signals in order to carry out said test is not necessary. Such storage would cause a limitation of the data volume used during the test, due to the non-expandable nature of the memory space provided for such storage. The invention therefore allows great flexibility in its application, and makes it possible to modify the test conditions, without having to make significant changes to the testing device such as an expansion of the memory space.

Moveover, in accordance with the invention, the test is interrupted as soon as a difference is detected between the output signals of the two integrated circuits, which allows a reduction of the overall cost of production of an integrated circuit by reducing the overall duration of the testing phase.

1. Integrated circuit testing device comprising:
input means (3) for generating input signals and applying these input signals to the input of an integrated circuit under test (1) and to the input of a reference integrated circuit that is considered to be in order (2), and
comparison means (4) for comparing in real time output signals delivered at the output of the integrated circuit under test (1) and at the output of the reference integrated circuit (2) in response to the input signals, in order to determine, dependent upon the result of the comparison, whether the integrated circuit under test (1) is in order or faulty characterized in that the integrated circuits (1, 2) are mounted in parallel and simultaneously receive the input signals, said input signals simulating the input signals that the integrated circuits (1, 2) would receive in a functional situation.

2. Testing device in accordance with claim 1, characterized in that the input means (3) comprise a central processing unit (30) intended to generate the input signals and to cooperate with an interface module (32), the interface module (32) connected on the one hand to the input of the integrated circuit under test (1) and on the other to the input of the reference integrated circuit (2) being intended to duplicate the input signals generated by the central unit (30) and intended for the integrated circuits (1, 2).

3. Testing device in accordance with claim 2, characterized in that it comprises connection means (13) intended to receive the integrated circuit under test (1), and in that the interface module (32) causes the connection means (13) to be powered down when an integrated circuit under test (1) is being installed.

4. Testing device in accordance with claim 2, characterized in that the interface module (32) is furthermore intended to supply clock signals to the integrated circuits (1, 2) and to the comparison means (4) to provide synchronization of the said integrated circuits (1, 2).

5. Testing device in accordance with claim 2, characterized in that the input means (3) comprise a data memory (31) intended to cooperate with the central processing unit (30), these data being the basis of the input signals.

6. Testing device in accordance with claim 2, characterized in that the input means (3) comprise a program memory (35) intended to cooperate with the central processing unit (30).

7. Testing device in accordance with claim 2, characterized in that the central processing unit (30) is connected to an interface (33) intended to communicate with a user via a microcomputer.

8. Testing device in accordance with claim 1, characterized in that the comparison means (4) are intended to perform a bit-by-bit comparison of the output signals.

9. Testing device in accordance with claim 8, characterized in that the comparison means (4) comprise at least one exclusive OR port (43).

10. Method of testing integrated circuits characterized in that it comprises the following steps:
generation of input signals to be applied simultaneously to the input of an integrated circuit under test (1) and to the input of a reference integrated circuit (2) considered to be in order, with these input signals simulating the input signals that the integrated circuit under test (1) and the reference integrated circuit (2) would receive in a functional situation;
comparison, in real time, of output signals appearing, in response to input signals, at the output of the integrated circuit under test (1) and at the output of the reference integrated circuit (2);
determination, dependent upon the result of the comparison, whether the integrated circuit under test (1) is in order or faulty.
